(19) United States
(12) Patent Application Publication
(10) Pub. No.: US 2016/0307740 A1
(43) Pub. Date: Oct. 20, 2016

(54) Substrate Processing System and Ceramic Coating Method Therefor

(71) Applicant: Samsung Electronics Co., Ltd., Suwon-si (KR)

(72) Inventors: Jungmin Kim, Seoul (KR); Jin Young Bang, Hwaseong-si (KR); Sejin Oh, Hwaseong-si (KR); Taekyun Kang, Hwaseong-si (KR); Myoung Soo Park, Seongnam-si (KR); Dougyong Sung, Seoul (KR)

(21) Appl. No.: 15/092,965

(22) Filed: Apr. 7, 2016

(30) Foreign Application Priority Data
Apr. 20, 2015 (KR) 10-2015-0055418

(51) Int. Cl. H01J 37/32; H01L 21/67

(52) U.S. Cl. CPC H01J 37/32467; H01L 21/67069; H01J 37/32495; H01J 37/32715; H01J 2237/3341

(57) ABSTRACT

A substrate processing system and a method of coating a ceramic layer therewith are provided. The system may include a chamber and a ceramic layer on an inner surface of the chamber. The ceramic layer may include yttrium oxyfluoride (YₓO_{y}F_{z}), where x=1, y=1, 2, and z=1, 2.

### CROSS-REFERENCE TO RELATED APPLICATIONS

This U.S. non-provisional patent application claims priority under 35 U.S.C. §119 to Korean Patent Application No. 10-2015-0055418, filed on Apr. 20. 2015, in the Korean Intellectual Property Office, the entire content of which is hereby incorporated by reference in its entirety.

### BACKGROUND OF THE INVENTION

Exemplary embodiments of the inventive concept relate to a substrate processing system, and in particular, to a system of processing a substrate using plasma reaction and a ceramic coating method therewith.

In general, semiconductor devices may be manufactured using a plurality of unit processes, such as a thin-film deposition process, a diffusion process, a thermal treatment process, a photolithography process, a polishing process, an etching process, an ion implantation process, and a cleaning process. Some of these processes (e.g., the etching process) may be performed using a plasma reaction. By using the plasma reaction, it is possible to enhance the straightness of the reaction gas in the etching process. However, the plasma reaction may lead to damage of an inner surface of a process chamber. In this case, particles may be produced from the damaged inner surface of the process chamber to result in a process failure of the etching process.

### SUMMARY

Exemplary embodiments of the inventive concept provide a substrate processing system capable of reducing a particle-induced failure of the etching process and a ceramic coating method therefor.

Other exemplary embodiments of the inventive concept provide a substrate processing system, which is configured to omit a seasoning process in a process of treating a substrate, and a ceramic coating method therefor.

According to an exemplary embodiment of the inventive concept, a substrate processing system and a method of coating a ceramic layer therewith are provided, The system may include a chamber and a ceramic layer on an inner surface of the chamber. The ceramic layer may include yttrium oxyfluoride (YₓO_{y}F_{z}), where x=1, y=1,2, and z=1, 2.

According to another exemplary embodiment of the inventive concept, a ceramic coating method using a substrate processing system may include providing a chamber, and forming a ceramic layer on an inner surface of the chamber. The forming of the ceramic layer may include forming yttrium oxyfluoride (YₓO_{y}F_{z}), where x=1, y=1, 2, and z=1, 2.

According to yet another exemplary embodiment of the inventive concept, a substrate processing system may include a chamber with a lower housing and an upper housing and a ceramic layer coated on an inner surface of the lower housing. The ceramic layer may include yttrium oxyfluoride, (YₓO_{y}F_{z}), where x=1, y=1, 2, and z=1, 2,

According to yet another exemplary embodiment of the inventive concept, the substrate processing system may include a buffer layer, or a plurality of buffer layers, between the ceramic layer and the inner surface of the chamber of the system.

### BRIEF DESCRIPTION OF THE DRAWINGS

Exemplary embodiments of the inventive concept. will be more clearly understood from the following brief description taken in conjunction with the accompanying drawings. The accompanying drawings represent non-limiting, example embodiment as described herein.

FIG. 1 is a sectional view schematically illustrating a substrate processing system according to an exemplary embodiment of the inventive concept.

FIG. 2 is an exploded sectional view illustrating a chamber of FIG. 1.

FIG. 3 is a sectional view exemplarily illustrating a wall liner and a ceramic layer according to an exemplary embodiment of the inventive concept.

FIG. 4 is a sectional view illustrating a conventional ceramic layer.

FIG. 5 is a graph showing an XPS depth profile obtained from the conventional ceramic layer of FIG. 4.

FIG. 6 is a graph showing an XPS depth profile obtained from the ceramic layer of FIG. 3.

FIG. 7 is a sectional view exemplarily illustrating a wall liner and a ceramic layer according to an exemplary embodiment of the inventive concept.

FIG. 8 is a sectional view exemplarily illustrating a wall liner and a ceramic layer according to an exemplary embodiment of the inventive concept.

FIG. 9 is a sectional view exemplarily illustrating a wall liner and a ceramic layer according to an exemplary embodiment of the inventive concept.

FIG. 10 is a flow chart illustrating a method of coating the ceramic layer according to an exemplary embodiment of the inventive concept.

FIG. 11 is a diagram schematically illustrating a process of forming a ceramic layer, according to an exemplary embodiment of the inventive concept.

FIG. 12 is a flow chart illustrating a method of coating the ceramic layer according to an exemplary embodiment of the inventive concept.

It should be noted that these figures are intended to illustrate the general characteristics of methods, structure and/or materials utilized in certain example embodiment and to supplement the written description provided below. These drawings are not, however, to scale and may not precisely reflect the precise structural or performance characteristics of any given embodiment, and should not be interpreted as defining or limiting the range of values or properties encompassed by example embodiment. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Exemplary embodiments of the inventive concept will now be described more fully with reference to the accompanying drawings, in which exemplary embodiments are shown. Exemplary embodiments of the inventive concepts may however, be embodied in many different forms and should not be construed as being limited to any of the particular embodiments set forth herein; rather, these embodiments are provided so that this disclosure will be thorough and complete, and will fully convey the concept of exemplary embodiments to those of ordinary skill in the art. In the drawings the thicknesses of layers and regions are exaggerated for clarity. Like reference numerals in the drawings denote like elements, and thus their description will be omitted.

It will be understood that when an element is referred to as being “on,” “connected to” or “coupled to” etc., another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, cements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the particular embodiment. As used herein, the singular forms “a,” “an” and “the” are intended to include the plural forms as well unless the context clearly indicates otherwise. It will be further understood that the terms “comprises”, “comprising”, “includes” and/or “including,” used herein, specify the presence of stated features, integers, steps, operations elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which the exemplary embodiment of the inventive concept belongs. It will be further understood that terms such as those defined in commonly-used dictionaries, should be interpreted as having a meaning that is consistent with their meaning in the context of the relevant art and will not be interpreted idealized or overly formal sense unless expressly so defined herein.

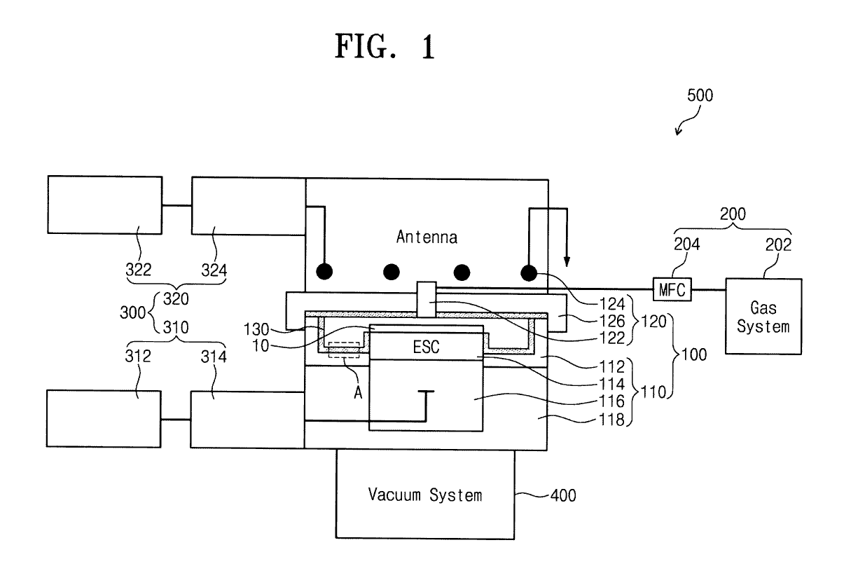

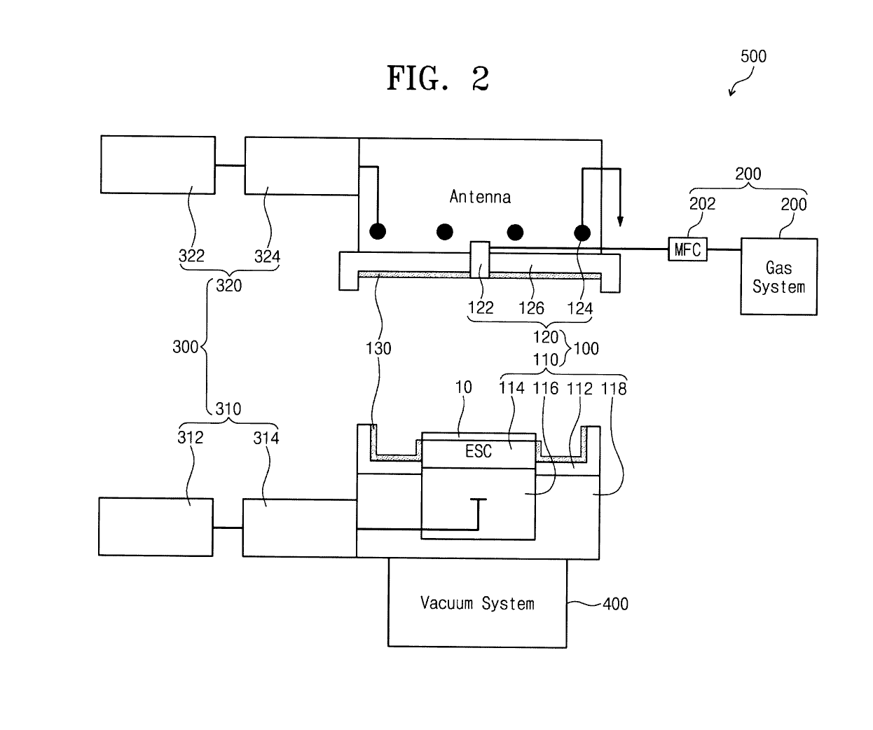

FIG. 1 is a sectional view schematically illustrating a substrate processing system 500 according to an exemplary embodiment of the inventive concept. FIG. 2 is an exploded sectional view illustrating a chamber 100 of FIG. 1.

Referring to FIGS. 1 and 2, the substrate processing system 500 may be an inductively coupled plasma etching system. In an exemplary embodiment, the substrate processing system 500 may include a chamber 100, a gas supplying unit 200, a high frequency power supply unit 300, and a pumping unit 400. The chamber 100 may be configured to perform a fabrication process on a substrate 10. For example, the fabrication process may include an etching process. The gas supplying unit 200 may be configured to supply a reaction gas into the chamber 100. The reaction gas may be an etching gas. The high frequency power supply unit 300 may be configured to apply high frequency power to the chamber 100. The pumping unit 400 may be configured to pump out air from the chamber 100.

The chamber 100 may provide an isolated space for performing the fabrication process on the substrate 10. In an exemplary embodiment, the chamber 100 may include a lower housing 110 and an upper housing 120. The substrate 10 may be provided on the lower housing 110. The upper housing 120 may be provided on the substrate 10 and the lower housing 110. The lower housing 110 and the upper housing 120 may be configured to be connected to or separated from each other.

In an exemplary embodiment, the lower housing 110 may include a wall liner 112, an electrostatic chuck 114, a bottom electrode 116, and a supporting block 118. The wall liner 112 may be fastened to the upper housing 120. The electrostatic chuck 114 may be provided in the wall liner 112. The electrostatic chuck 114 may be configured to fasten the substrate 10. The reaction gas may flow through a space between the substrate 10 and the upper housing 120. The bottom electrode 116 may be provided below the electrostatic chuck 114. The bottom electrode 116 may be applied with the high frequency power that is transmitted from the high frequency power supply unit 300. The high frequency power may allow the reaction gas to be concentrated onto the substrate 10. The supporting block 118 may be configured to support the wall liner 112 and the bottom electrode 116. Although not shown, a lifter may be further provided to control a vertical position of the supporting block 118.

The upper housing 120 may be provided on the lower housing 110. The upper housing 120 may include a gas nozzle 122, a plasma antenna 124, and a window 126. The window 126 may be disposed on the substrate 10. The plasma antenna 124 may be disposed on the window 126. The gas nozzle 122 may be disposed on a center of the substrate 10 through the window 126. The gas nozzle 122 may be connected to the gas supplying unit 200. The gas nozzle 122 may provide the reaction gas on the substrate 10. The plasma antenna 124 may induce the plasma reaction of the reaction gas, using the high frequency power. The window 126 may include a dielectric. The window 126 may protect the plasma antenna 124 from the reaction gas and/or the plasma reaction.

The pumping unit 400 may be provided below the lower housing 110. The pumping unit 400 may be used to exhaust the reaction gas from the space between the lower housing 110 and the upper housing 120, when the fabrication process is finished. As an example, the pumping unit 400 may include a vacuum pump.

The gas supplying unit 200 may be connected to the upper housing 120. The gas supplying unit 200 may include a gas storage unit 202 and a mass flow control valve 204. The gas storage unit 202 may be configured to store the reaction gas. The mass flow control valve 204 may be provided on a conduit connecting the gas storage unit 202 to the upper housing 120. The mass flow control valve 204 may be used to adjust a flow rate of the reaction gas to be supplied into the chamber 100.

The high frequency power supply unit 300 may be configured to apply the high frequency power to the bottom electrode 116 and the plasma antenna 124. The high frequency power supply unit 300 may include a first high frequency power supply unit 310 and a second high frequency power supply unit 320. The first high frequency power supply unit 310 may be connected to the bottom electrode 116. The first high frequency power supply unit 310 may include a first high frequency generator 312 and a first matcher 314. The first high frequency generator 312 may be configured to generate a high frequency power. The first matcher 314 may be connected between the first high frequency generator 312 and the bottom electrode 116. The first matcher 314 may be used for impedance matching of the high frequency power. The second high frequency power supply unit 320 may be connected to the plasma antenna 124. The second high frequency power supply unit 320 may include a second high frequency generator 322 and a second matcher 324. The second high frequency generator 322 may be configured to generate a high frequency power. The second matcher 324 may be connected between the second high frequency generator 322 and the plasma antenna 124. The second matcher 324 may be used for impedance matching of the high frequency power. An intensity of the plasma reaction may be proportional to the magnitude of the high frequency power.

If the upper housing 120 is separated from the lower housing 110, the substrate 10 may be loaded on the electrostatic chuck 114 by a delivering unit (not shown). Thereafter, if the upper housing 120 is engaged to the lower housing 110, the reaction gas may be supplied onto the substrate 10 through the upper housing 120. The reaction gas may be concentrated on the electrostatic chuck 114 and the wall liner 112, by the high frequency power of the bottom electrode 116.

A ceramic layer 130 may be provided on a top surface of the lower housing 110. In certain embodiments, the ceramic layer 130 may also be provided on a bottom surface of the upper housing 120. The ceramic layer 130 may protect an inner surface of the chamber 100 from the reaction gas.

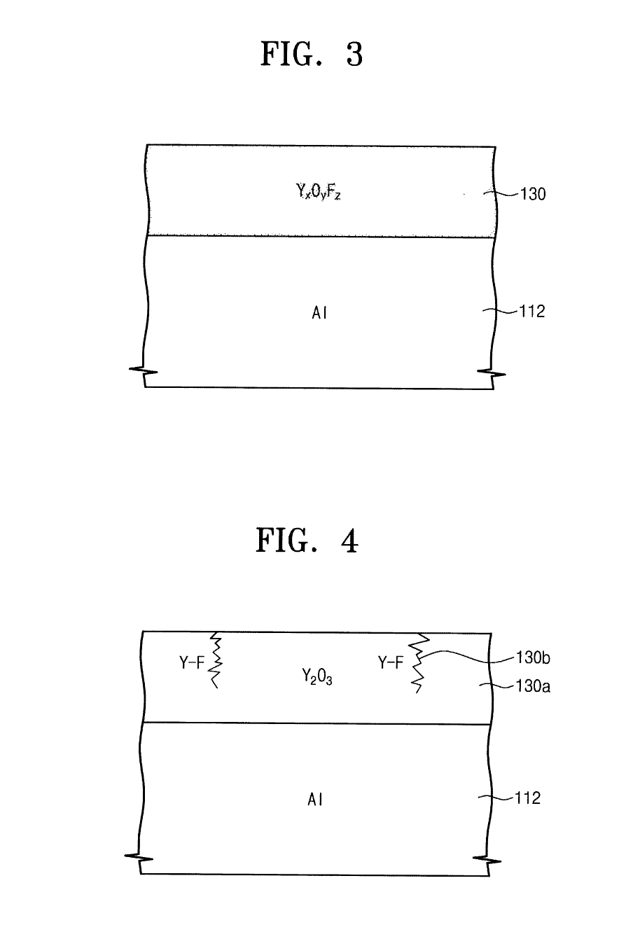

FIG. 3 is a sectional view exemplarily illustrating the wall liner 112 and the ceramic layer 130 (e.g., a portion A of FIG. 1), according to an exemplary embodiment of the inventive concept.

Referring to FIGS. 1 and 3, the ceramic layer 130 may be provided on the wall liner 112. For example, a top surface of the wall liner 112 may correspond to an inner surface of the chamber 100. The ceramic layer 130 may be provided on a portion of the electrostatic chuck 114 exposed by the substrate 10. In an exemplary embodiment, the wall liner 112 may be formed of or include aluminum (Al). For example, the wall liner 112 may include an aluminum-containing layer formed by an anodic oxidation method. The ceramic layer 130 may be formed of or include yttrium oxyfluoride (YₓO_{y}F_{z}, x=1, y=1, 2, and z=1, 2) (e g., YOF, YO₂F, or YOF₂).

As an example. YOF may have a chemical structure given by the following chemical formula 1.

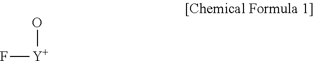

Here, Y′ is an yttrium on bonded with oxygen (O) and fluorine (F). Since, in YOF, yttrium (Y) is in an ion state, it may have reactivity higher than those of oxygen (O) and fluorine (F).

As another example, YO₂F may have a chemical structure given by the following chemical formula 2.

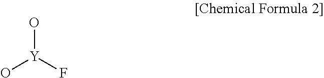

Here, yttrium (Y) is bonded with two oxygen atoms and one fluorine atom. The bonds of yttrium (Y) and oxygen (O) (Le, Y—O) are more than the bond of yttrium (Y) and fluorine (F) (i.e., Y—F). YO₂F may have reactivity lower than the YOF, with respect to the fluorine (F).

As yet another example, YOF₂ may have a chemical structure given by the following chemical formula 3.

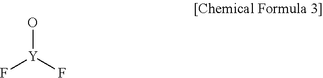

Here, yttrium (Y) is bonded with one oxygen atom and two fluorine atoms. The bonds of yttrium (Y) and fluorine (F) (i.e., Y—F) are more than the bond of yttrium (Y) and oxygen (O) (i.e., Y—O). in the bonds of yttrium (Y) and oxygen (O) (i.e., Y—O), the oxygen (O) may reduce the corrosion of YOF₂. The YOF₂ may have reactivity lower than the YO₂F, with respect to the fluorine (F).

As described above, the yttrium oxyfluoride (YₓO_{y}F_{z}) may have chemical resistance to a fluorine-containing reaction gas, A relationship between the fluorine (F) of the reaction gas and the yttrium oxyfluoride (YₓO_{y}F_{z}) will be described below.

FIG. 4 is a sectional view illustrating a ceramic layer 130a according to the conventional technology.

Referring to FIG. 4, the conventional ceramic layer 130a may contain yttrium oxide (Y₂O₃). A layer of yttrium oxide (Y₂O₃) may be easily damaged by a reaction gas containing fluorine (F). For example, the fluorine (F) may be bonded with yttrium (Y) in the ceramic layer 130a. Such a bond of yttrium (Y) and fluorine (F) (i.e., Y—F) may lead to progressive cracks, e.g., 130b, in the ceramic layer 130a. Furthermore, the progressive cracks 130b may lead to particle contamination resulting from the damage to the ceramic layer.

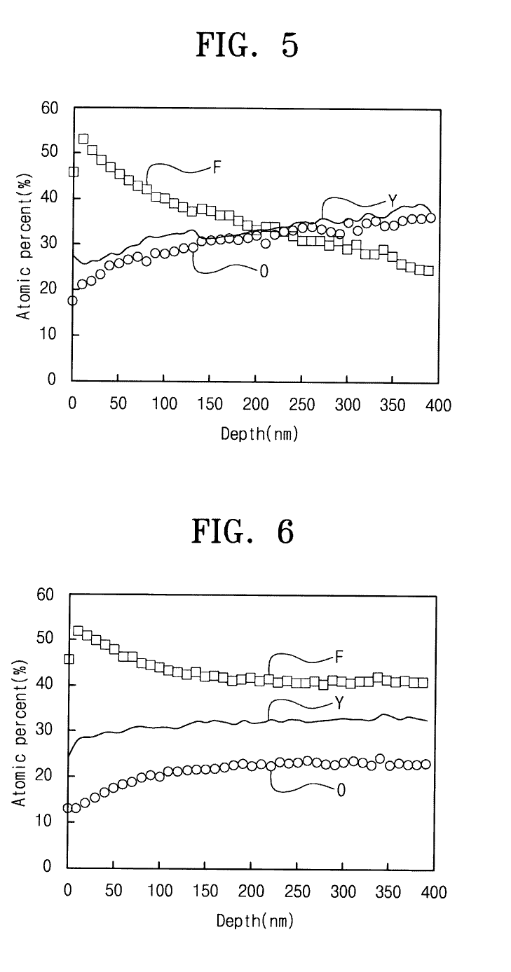

FIG. 5 is a graph showing an X-ray photoelectron spectroscopy (XPS) depth profile obtained from the conventional ceramic layer 130a of FIG. 4.

Referring to FIGS. 4 and 5, the conventional ceramic layer 130a was exposed to the reaction gas for 30 hours or more, and in this case, a content of the fluorine (F) increased to a depth of about 20 nm and then gradually decreased in a depth direction of the ceramic layer 130a. The fluorine (F) contained in the reaction gas may be infiltrated into the ceramic layer 130a. The infiltrated fluorine (F) may serve as the cause of the progressive crack 130b in an yttrium oxide (Y₂O₃) layer. The yttrium (Y) and the oxygen (O) increased gradually in the depth direction and were similar to each other at a depth of about 20 nm or greater, in terms of their content.

FIG. 6 is a graph showing an XPS depth profile obtained from the ceramic layer 130 of FIG. 3.

Referring to FIGS. 3 and 6, the ceramic layer 130 according to an exemplary embodiment of the inventive concept had relatively stable contents of yttrium (Y), oxygen (O), and fluorine (F), even when it was exposed to the reaction gas for 10 hours or more. For example, a content of the fluorine (F) was decreased to a depth of about 200 nm. Furthermore, the content of the fluorine (F) was substantially stable at a depth of about 200 nm or larger. The fluorine (F) and yttrium (Y) of the ceramic layer 130 were bonded to each other with a stable bonding energy. The content of fluorine (F) and yttrium (Y) were maintained similar to that of an initial state before the ceramic layer 130 had been exposed to the reaction gas. The ceramic layer 130 may prevent the fluorine (F) contained in the reaction gas from being infiltrated into an underlying layer. Even in the case where the ceramic layer 130 is exposed to the fluorine (F), a surface of the ceramic layer 130 exhibits a very small change in chemical structure, and thus, it is possible to suppress the progressive crack 130b from occurring in the ceramic layer 130. In other words, the ceramic layer 130 may not be damaged by the reaction gas, thereby reducing occurrence of particles.

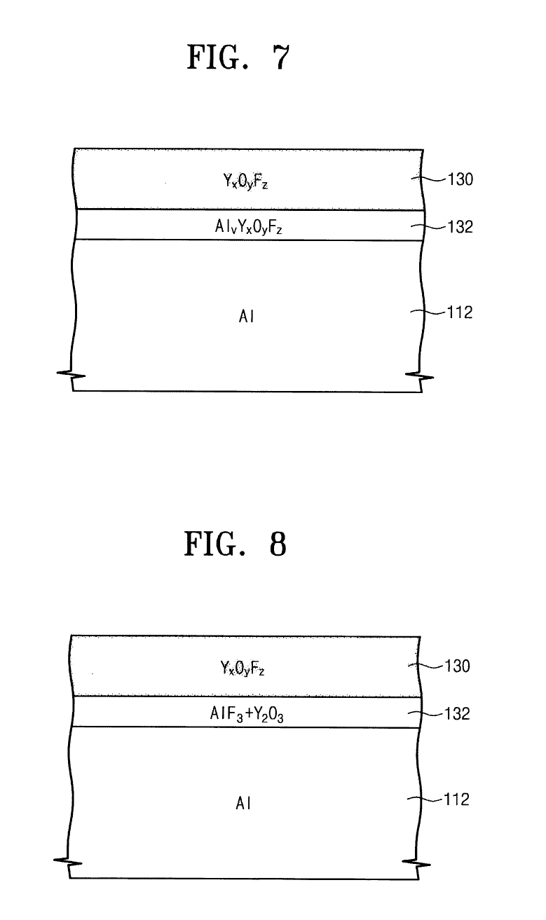

FIG. 7 is a sectional view exemplarily illustrating the wall liner 112 and the ceramic layer 130 (e.g., the portion A of FIG. 1) according to an exemplary embodiment of the inventive concept.

Referring to FIG. 7, a buffer layer 132 may be provided between the wall liner 112 and the ceramic layer 130. The wall liner 112 and the ceramic layer 130 may be provided to have substantially the same features as those of FIG. 3. For example, the buffer layer 132 may be formed of or include an aluminum yttrium oxyfluoride (AlᵥYₓO_{y}F_{z}) layer, where v=1, 2, x=1, y=1, 2, and z=1, 2. In the buffer layer 132, a content of the aluminum (Al) may increase in a direction toward the wall liner 112 and a content of the fluorine (F) may decrease in a direction toward the wall liner 112. In an exemplary embodiment, the buffer layer 132 may contribute to reduce technical issues, which may be caused by a difference in thermal expansion coefficient between the wall liner 112 and the ceramic layer 130. The buffer layer 132 may have a thermal expansion coefficient higher than that of the wall liner 112 and lower than that of the ceramic layer 130. The aluminum layer may have a thermal expansion coefficient of about 22×10⁻⁶/K, and the yttrium oxyfluoride layer may have a thermal expansion coefficient of about 28×10⁻⁶/K. The aluminum yttrium oxyfluoride (AlᵥYₓO_{y}F_{z}) layer may have a thermal expansion coefficient that is higher than about 22×10⁻⁶/K and lower than about 28×10⁻⁶/K.

FIG. 8 is a sectional view exemplarily illustrating the wall liner 112 and the ceramic layer 130 (e.g., the portion A of FIG. 1) according to an exemplary embodiment of the inventive concept.

Referring to FIG. 8, the buffer layer 132 may be formed of or include a mixture of aluminum fluoride (AlF₃) and yttrium oxide Y₂O₃. The mixture of AlF₃ and Y₂O₃ may have a thermal expansion coefficient higher than that of the aluminum layer. in addition, the mixture of AlF₃ and Y₂O₃ may have a thermal expansion coefficient lower than that of the yttrium oxyfluoride (YₓO_{y}F_{z}) layer.

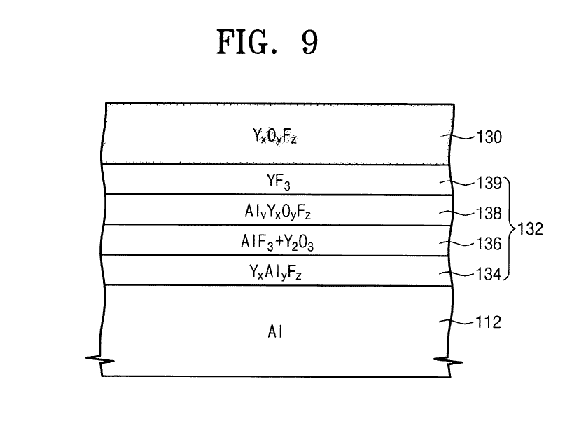

FIG. 9 is a sectional view exemplarily illustrating the wall liner 112 and the ceramic layer 130 (e.g., the portion A of FIG. 1) according to an exemplary embodiment of the inventive concept.

Referring to FIG. 9, the buffer layer 132 may include a first buffer layer 134, a second buffer layer 136, a third buffer layer 138, and a fourth buffer layer 139. The buffer layer 132 may be configured to gradually reduce a difference in thermal expansion coefficient between the wall liner 112 and the ceramic layer 130. The first buffer layer 134 may be provided on the wall liner 112. A thermal expansion coefficient of the first buffer layer 134 may be higher than that of the wall liner 112. The first buffer layer 134 may be formed of or include an aluminum yttrium fluoride (AlᵥYₓF_{z}) layer, where v=1, 2, x=1, and z=1, 2. The second buffer layer 136 may be provided on the first buffer layer 134. A thermal expansion coefficient of the second buffer layer 136 may be higher than that of the first buffer layer 134. The second buffer layer 136 may be formed of or include a mixture of aluminum fluoride (AlF₃) and yttrium oxide (Y₂O₃). A third buffer layer 138 may be provided on the second buffer layer 136, A thermal expansion coefficient of the third buffer layer 138 may be higher than that of the second buffer layer 136 and lower than that of the ceramic layer 130. The third buffer layer 138 may be formed of or include an aluminum yttrium oxyfluoride (AlᵥYₓO_{y}F_{z}) layer, where v=1, 2, x=1, y=1, 2, and z=1, 2. A content of the aluminum (Al) may increase in a depth direction of the buffer layer 132 For example, the content of the aluminum (Al) may be higher in the second buffer layer 136 than in the third buffer layer 138 and may be higher in the first buffer layer 134 than in the second buffer layer 136. By contrast, the content of the fluorine (F) may decrease in the depth direction of the buffer layer 132. For example, the content of the fluorine (F) may be lower in the second buffer layer 136 than in the third buffer layer 138 and may be lower in the first buffer layer 134 than in the second buffer layer 136. The fourth buffer layer 139 may be provided on the third buffer layer 138. A thermal expansion coefficient of the fourth buffer layer 139 may be higher than that of the third buffer layer 138 and lower than that of the ceramic layer 130. The fourth buffer layer 139 may be formed of or include an yttrium fluoride (YF₃) layer,

Meanwhile, the ceramic layer 130 may reduce the change in etch rate of the etching process. The change in etch rate of the conventional ceramic layer 130a may be high (e.g., about 5.8%), at an initial stage of an etching process after preventive maintenance. Accordingly, if the conventional ceramic layer 130a is used, it is necessary to perform a seasoning process for about 5 hours. in contrast, the change in etch rate of the ceramic layer 130 according to an exemplary embodiment of the inventive concept may be low (e.g., about 2.5%) at an initial stage of an etching process after preventive maintenance. Thus, if the ceramic layer 130 is used, it is possible to omit a seasoning process, In other words, in the case where the ceramic layer 130 according to a exemplary embodiment of the inventive concept is used, an etching process may be performed without any seasoning process, and this makes it possible to reduce a process back-up time. Here, the process back-up time may be defined as a time between the preventive maintenance step and an etching process.

Hereinafter, a method of forming the ceramic layer 130 on the substrate processing system 500 will be described in more detail.

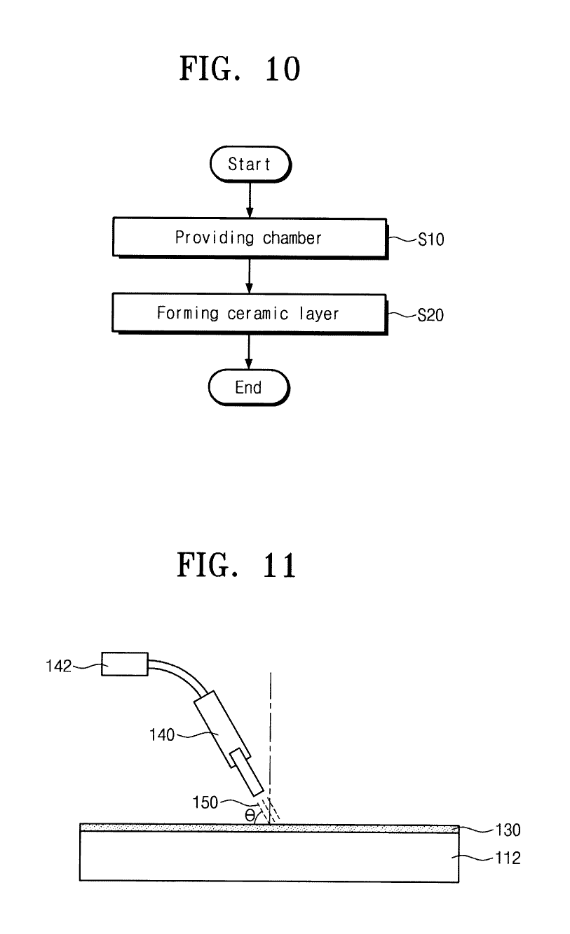

FIG. 10 is a flow chart illustrating a method of coating the ceramic layer 130, according to an exemplary embodiment of the inventive concept.

Referring to FIG, 10, a process of forming the ceramic layer 130 may include providing the chamber 100 (in S10) and forming the ceramic layer 130 (in S20). The providing of the chamber 100 (in S10) may include performing a preventive maintenance step on the chamber 100. The preventive maintenance step may be a wet cleaning step. The forming of the ceramic layer 130 (in S20) may include at least one of a thermal spraying method, an aerosol method, an electron beam deposition method, or a chemical vapor deposition method.

FIG. 11 is a diagram schematically illustrating the step S20 of forming the ceramic layer 130 of FIG. 10, according to an exemplary embodiment of the inventive concept.

Referring to FIG. 11, the ceramic layer 130 may be formed by a spray gun 140 and using a thermal spraying method. Yttrium oxyfluoride particles 150 may be supplied from a storage unit 142 to a spray gun 140. The spray gun 140 may be configured to spray the yttrium oxyfluoride particles 150 onto the wall liner 112. For example, the yttrium oxyfluoride particles 150 may have a diameter of about 10 μm or smaller. The spray gun 140 may be configured to heat the yttrium oxyfluoride particles 150 to about 200° C. or higher. The ceramic layer 130 may be formed to have porosity of about 1% or lower.

In an exemplary embodiment, the yttrium oxyfluoride particles 150 may be incident onto the wall liner 112 and the ceramic layer 130 at a spraying angle θ0 ranging from about 45° to about 90°. If the spraying angle θ of the yttrium oxyfluoride particles 150 ranges from 0° to 45°, a coating failure may occur on the ceramic layer 130. As an example of such a coating failure, the ceramic layer 130 may suffer a change in surface color thereof. The change in the surface color may be suppressed by reducing a surface roughness of the ceramic layer 130. In the case where the ceramic layer 130 has a reduced surface roughness, it is possible to reduce adsorption of side products, which may occur in an etching process.

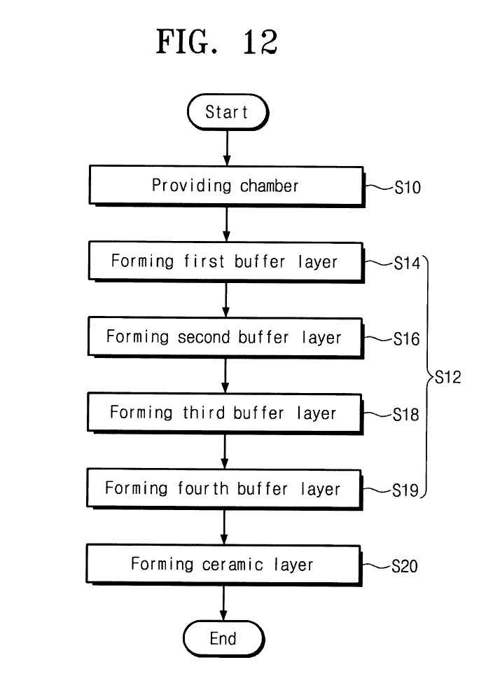

FIG. 12 is a flow chart illustrating a method of coating the ceramic layer 130, according to an exemplary embodiment of the inventive concept.

Referring to FIG. 12, a process of forming the ceramic layer 130 may include providing the chamber 108 (in S10), forming the buffer layer 132 (in S12), and forming the ceramic layer 130 (in S20). The providing of the chamber 100 (in S10) and the forming of the ceramic layer 130 (in S20) may be the same as those previously described with reference to FIG. 10.

The forming of the buffer layer 132 (in S12) may include steps S14, S16, S18, and S19 of forming first to third buffer layers 134, 136, 138, and 139, respectively. The forming of the first buffer layer 134 (in S14) may include forming an aluminum yttrium fluoride (AlᵥYₓ,F_{z}) layer on the wall liner 112. The forming of the second buffer layer 136 (in S16) may include forming a mixture of aluminum fluoride (AlF₃) and yttrium oxide (Y₂O₃) on the first buffer layer 134. The forming of the third buffer layer 138 (in S18) may include forming an aluminum yttrium oxyfluoride (AlᵥYₓO_{y}F_{z}) layer on the second buffer layer 136. The forming of the fourth buffer layer 139 (in S19) may include an yttrium fluoride (YF₃) layer on the third buffer layer 138.

According to an exemplary embodiment of the inventive concept, a substrate processing system may include a chamber, whose inner surface is coated with a ceramic layer made of a fluorine-containing material (e.g., yttrium oxyfluoride (YOF)). The ceramic layer may suppress the inner surface of the chamber from being damaged by a plasma reaction, and thus, it is possible to prevent a particle contamination due to damage of the ceramic layer from occurring. Furthermore, the ceramic layer may reduce a change in etch rate of an etching process, and this may make it possible to omit a seasoning process of the chamber.

While exemplary embodiments of the inventive concept have been particularly shown and described, it will be understood by one of ordinary skill in the art that variations in form and detail may be made therein without departing from the spirit and scope of the attached claims.

1. A substrate processing system, comprising:
a chamber; and
a ceramic layer on an inner s face of the chamber,
wherein the ceramic layer comprises yttrium oxyfluoride (YₓO_{y}F_{z}), wherein x=1, y=1, 2, and z=1, 2.

2. The system of claim 1, wherein the inner surface of the chamber is formed of an aluminum-containing material,
wherein the system further comprises a buffer layer provided between the inner surface of the chamber and the ceramic layer.

3. The system of claim 2, wherein the buffer layer has a thermal expansion coefficient that is higher than a thermal expansion coefficient of the inner surface of the chamber and lower than a thermal expansion coefficient of the ceramic layer

4. The system of claim 2, wherein the buffer layer comprises aluminum yttrium oxyfluoride (AlᵥYₓO_{y}Fₓ), wherein v=1, 2, x=1, y=1, 2, and z=1, 2.

5. The system of claim 2, wherein the buffer layer comprises a mixture of aluminum fluoride and yttrium oxide.

6. The system of claim 2, wherein the buffer layer comprises:
a first buffer layer on the inner surface, the first buffer layer comprising aluminum yttrium fluoride;
a second buffer layer on the first buffer layer;
a third buffer layer on the second buffer layer; and
a fourth buffer layer on the third buffer layer.

7. The system of claim 6, wherein the second buffer layer comprises a mixture of aluminum fluoride and yttrium oxide.

8. The system of claim 6, wherein the third buffer layer comprises aluminum yttrium oxyfluoride.

9. The system of claim 6, wherein the fourth buffer layer comprises yttrium fluoride.

10. The system of claim 6. wherein the ceramic layer has a thermal expansion coefficient that is higher than a thermal expansion coefficient of the fourth buffer layer, the fourth buffer layer has a thermal expansion coefficient that is higher than a thermal expansion coefficient of the third butler layer, the third buffer layer has a thermal expansion coefficient that is higher than a thermal expansion coefficient of the second buffer layer, the second buffer layer has a thermal expansion coefficient that is higher than the thermal expansion coefficient of the first buffer layer, and the first buffer layer has a higher thermal expansion coefficient than the thermal coefficient of the inner surface of the chamber.

11. The system of claim 6, wherein an aluminum content in the first buffer layer is greater than an aluminum content in the second buffer layer, the aluminum content in the second buffer layer is greater than an aluminum content in the third buffer layer, and the aluminum content in the third buffer layer is greater than an aluminum content in the fourth buffer layer.

12. The system of claim 1, wherein the chamber comprises:
a lower housing, on which a substrate is loaded; and
an upper housing provided on the lower housing and configured to supply a reaction gas onto the substrate.

13. The system of claim 12, wherein the lower housing comprises:
a chuck configured to receive the substrate; and
a wall liner configured to be fastened to the upper housing to enclose the chuck,
wherein the yttrium oxyfluoride is coated on the wall liner.

14-20. (canceled)
